(19) United States
(12) Patent Application Publication
(10) Pub. No.: US 2015/0114693 A1
(43) Pub. Date: Apr. 30, 2015

(54) INSULATING RESIN COMPOSITION FOR PRINTED CIRCUIT BOARD AND PRODUCTS MANUFACTURED BY USING THE SAME

(71) Applicant: Samsung Electro-Mechanics Co., Ltd., Suwon-Si (KR)

(72) Inventors: Jin Seok Moon, Suwon-Si (KR); Geum Hee Yun, Suwon-Si (KR); Dae Hui Jo, Suwon-Si (KR); Seong Hyun Yoo, Suwon-Si (KR); Hyun Jun Lee, Suwon-Si (KR); Jin Young Kim, Suwon-Si (KR); Keung Jin Sohn, Suwon-Si (KR)

(73) Assignee: Samsung Electro-Mechanics Co., Ltd., Suwon-Si (KR)

(21) Appl. No.: 14/195,665

(22) Filed: Mar. 3, 2014

(30) Foreign Application Priority Data
Oct. 25, 2013 (KR) 10-2013-0127918

(51) Int. Cl. C08L 63/00; H05K 1/03; H05K 1/02; C08L 65/02

(52) U.S. Cl. CPC C08L 63/00; C08L 65/02; H05K 1/0366; H05K 1/0271
USPC 174/255; 525/113; 523/467; 523/468

(57) ABSTRACT

Disclosed herein are an insulating resin composition for a printed circuit board, and an insulating film, a prepreg, a copper clad laminate, or a printed circuit board manufactured by using the same. More specifically, the insulating resin composition contains an eucryptite inorganic filler having a negative coefficient of thermal expansion, such that a glass transition temperature and a coefficient of thermal expansion may be improved, and warpage of the insulating film, the prepreg, the copper clad laminate, or the printed circuit board manufactured by using the insulating resin composition for a printed circuit board may be minimized.

### CROSS REFERENCE TO RELATED APPLICATION

This application claims the benefit of Korean Patent Application No. 10-2013-0127918, filed on Oct. 25, 2013, entitled “Insulating Resin Composition for Printed Circuit Board and Products Manufactured by Using the Same”, which is hereby incorporated by reference in its entirety into this application.

### BACKGROUND OF THE INVENTION

1. Technical Field

The present invention relates to an insulating resin composition for a printed circuit board and products manufactured by using the same.

2. Description of the Related Art

In accordance with development of electronic devices, a printed circuit board has progressed to have a light weight, a thin thickness, and a small size. In order to satisfy the demand in lightness and slimness as described above, wirings of the printed circuit board become more complicated and have higher density. Electrical, thermal, and mechanical properties required for a substrate as described above function as a more important factor. The printed circuit board consists of copper mainly serving as a circuit wiring and a polymer serving as an interlayer insulation. As compared to copper, various properties such as coefficient of thermal expansion, glass transition temperature, and thickness uniformity, are demanded in a polymer configuring an insulating layer, in particular, the insulating layer should be designed so as to have a thin thickness.

As the circuit board becomes thin, the board itself has decreased stiffness, causing defects due to a bending phenomenon at the time of mounting components thereon at a high temperature. Therefore, thermal expansion property and heat-resistant property of a heat curable polymer resin function as an important factor, that is, at the time of heat curing, network between polymer chains configuring a polymer structure and a substrate composition and curing density are closely affected.

In the prior art, an insulating resin composition for a printed circuit board containing general conventional epoxy resins and inorganic fillers such as silica, and the like, has been used to decrease coefficient of thermal expansion and glass transition temperature. However, according to the prior art, the coefficient of thermal expansion and the glass transition temperature may be improved; however, modulus and thermal stability are decreased. In addition, there is a limitation in improving the coefficient of thermal expansion and the glass transition temperature.

Meanwhile, Patent Document 1 discloses a resin composition for a printed circuit board, but has a limitation in sufficiently forming interaction network between compositions, such that coefficient of thermal expansion and glass transition temperature of the printed circuit board are not improved.

### PRIOR ART DOCUMENT

### Patent Document

Patent Document 1 Korean Patent Laid-Open Publication No. 2011-0108782

### SUMMARY OF THE INVENTION

The present invention has been made in an effort to provide an insulating resin composition for a printed circuit board having improved glass transition temperature (Tg) and coefficient of thermal expansion (CTE) by using an insulating resin composition containing an eucryptite inorganic filler surface-treated with a coupling agent.

In addition, the present invention has been made in an effort to provide a prepreg containing the insulating resin composition.

Further, the present invention has been made in an effort to provide a printed circuit board manufactured by stacking at least one circuit layer and insulating layer on one surface or the other surface of the prepreg.

According to a preferred embodiment of the present invention, there is provided an insulating resin composition for a printed circuit board including: a naphthalene-based epoxy resin; a bismaleimide resin; a cyanate ester resin; a coupling agent; and an eucryptite inorganic filler.

The naphthalene-based epoxy resin may be contained in a content of 5 to 30 wt %, the bismaleimide resin may be contained in a content of 1 to 10 wt %, the cyanate ester resin may be contained in a content of 5 to 30 wt %, the coupling agent may be contained in a content of 0.1 to 5 wt %; and the eucryptite inorganic filler may be contained in a content of 50 to 80 wt %.

The naphthalene-based epoxy resin may be a methane typed naphthalene-based epoxy resin represented by the following Chemical Formula 1, an ester typed naphthalene-based epoxy resin represented by the following Chemical Formula 2 or 3, or a mixture thereof:

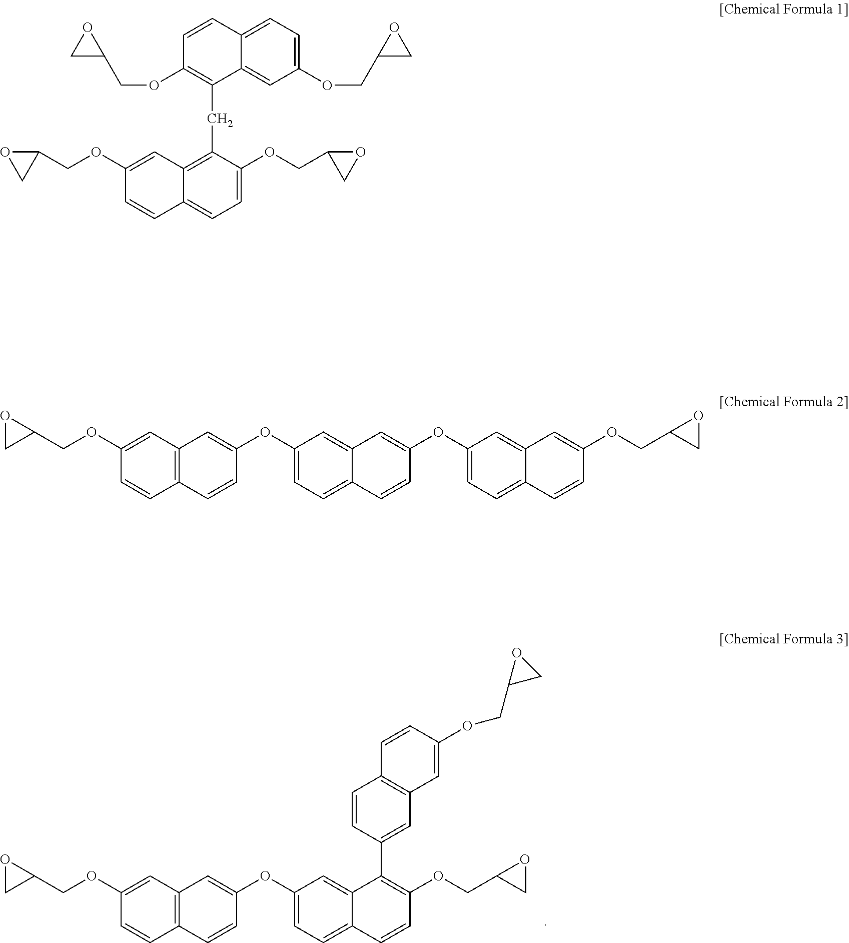 [SMILES: c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

The bismaleimide resin may be an oligomer of phenyl methane maleimide represented by the following Chemical Formula 4:

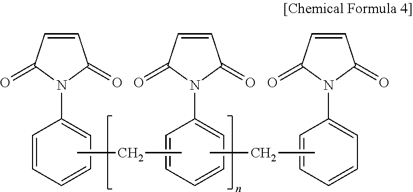

in Chemical Formula 4, n is an integer of 0 to 2.

The cyanate ester resin may be a phenol novolac typed cyanate ester resin represented by the following Chemical Formula 5:

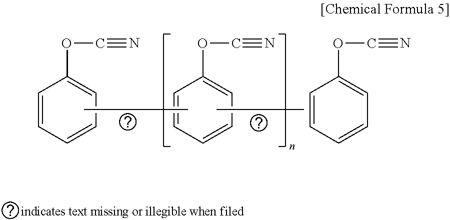

in Chemical Formula 5, n is an integer of 0 to 3.

The coupling agent may be a silane-based coupling agent.

The euciyptite inorganic filler may be represented by the following Chemical Formula 6:

xLi₂0-yAl₂O₃-zSiO₂ [Chemical Formula 6]

in Chemical Formula 6, each x, y and z represents a mixing molar ratio, x and y are each independently 0.9 to 1.1, and z is 1.2 to 2.1.

The insulating resin composition may further include a curing agent, a curing accelerator, and an initiator.

The curing agent may be at least one selected from an amine-based curing agent, an acid anhydride-based curing agent, a polyamine curing agent, a polysulfide curing agent, a phenol novolac typed curing agent, a bisphenol A typed curing agent, and a dicyandiamide curing agent.

The curing accelerator may be at least one selected from a metal-based curing accelerator, an imidazole-based curing accelerator, and an amine-based curing accelerator.

The initiator may be at least one selected from azobisisobutyronitrile (AILBN), dicumyl peroxide (DCT) and di-tertiarybutyl peroxide (DTBP).

According to another preferred embodiment of the present invention, there is provided a prepreg prepared by impregnating an inorganic fiber or an organic fiber into a varnish containing the insulating resin composition for a printed circuit board as described above.

The inorganic fiber or the organic fiber may be at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

According to another preferred embodiment of the present invention, there is provided a printed circuit board manufactured by stacking at least one circuit layer and insulating layer on one surface or the other surface of the prepreg as described above.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view schematically showing a constitution of an insulating resin composition for a printed circuit board according to a preferred embodiment of the present invention.

### DESCRIPTION OF THE PREFERRED EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define a concept implied by a term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

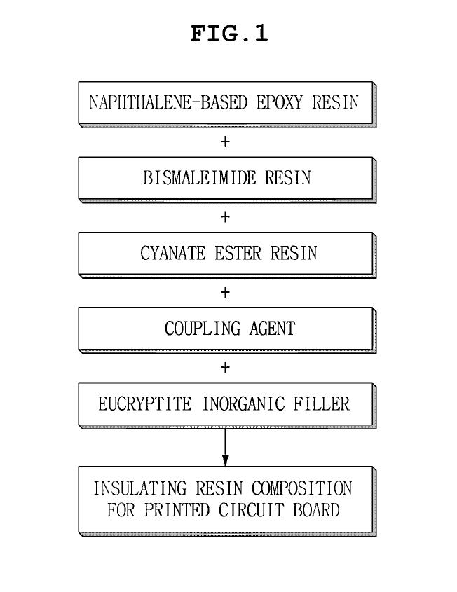

FIG. 1 is a view schematically showing a constitution of an insulating resin composition for a printed circuit board according to a preferred embodiment of the present invention. Referring to FIG. 1, according to the insulating resin composition containing an eucryptite inorganic filler having a negative coefficient of thermal expansion and products manufactured by using the same, glass transition temperature and coefficient of thermal expansion may be improved.

Insulating Resin Composition

Epoxy Resin

The insulating resin composition for a printed circuit board according to the preferred embodiment of the present invention may contain an epoxy resin in order to increase a handling property as an insulating product manufactured by using a resin composition after performing a drying process. The epoxy resin includes one or more epoxy functional groups in a molecule, wherein the epoxy resin including four or more epoxy functional groups may be appropriate for improving a bonding strength.

The epoxy resin may be at least one selected from a naphthalene-based epoxy resin, a bisphenol A typed epoxy resin, a phenol novolac epoxy resin, a cresol novolac epoxy resin, a rubber-modified epoxy resin, a phosphorous-based epoxy resin, and a bisphenol F typed epoxy resin, and among them, the naphthalene-based epoxy resin may be the most appropriate, but the present invention is not necessarily limited thereto.

The naphthalene-based epoxy resin may improve heat-resistant property in the resin composition, and epoxide functional groups introduced at ends of the epoxy resin may be easily packed at the time of curing the resin composition. In addition, a phenomenon that planar chromophores such as an aromatic ring, and the like, are overlapped and stacked with each other due to dispersion or hydrophobic interaction, that is, a stacking structure may be formed to minimize deformation by heat.

The naphthalene-based epoxy resin may be a methane typed naphthalene-based epoxy resin represented by the following Chemical Formula 1, an ester typed naphthalene-based epoxy resin represented by the following Chemical Formula 2 or 3, or a mixture thereof:

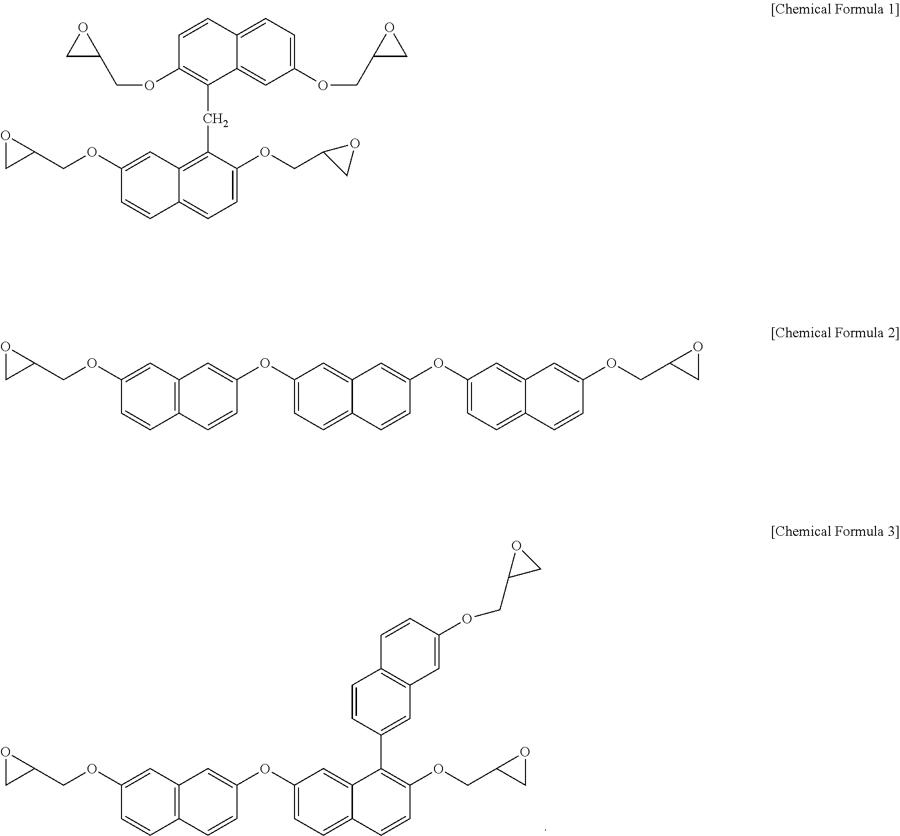 [SMILES: c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

The naphthalene-based epoxy resin represented by the Chemical Formula 1, 2, or 3 above may have a rigid structure to have thermal stability. In addition, the naphthalene-based epoxy resin may constitute an interconnect network with a bismaleimide resin and may have high heat-resistant property.

In the insulating resin composition according to the preferred embodiment of the present invention, it is appropriate that the epoxy resin is used in a content of 5 to 30 wt %, but the content of the used epoxy resin is not specifically limited thereto. In the case in which the content of the used epoxy resin is less than 5 wt %, adhesion of the resin composition is deteriorated and a curing temperature is increased, such that flame retardancy may be deteriorated, and in the case in which the content thereof is more than 30 wt %, a dielectric constant of the resin composition is increased, such that mechanical strength may be deteriorated.

Bismaleimide Resin

The insulating resin composition for a printed circuit board according to the preferred embodiment of the present invention may contain a bismaleimide resin for improving heat-resistant property in the resin composition.

The bismaleimide resin may be an oligomer of phenyl methane maleimide represented by the following Chemical Formula 4:

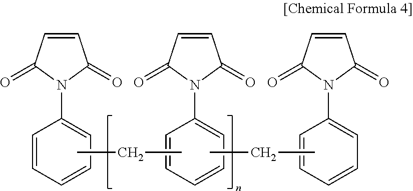

in Chemical Formula 4, n is an integer of 0 to 2.

The oligomer of phenyl methane maleimide may constitute the network interconnected with the naphthalene-based epoxy resin in the resin composition, which achieve a synergy effect to further improve thermal property.

In the insulating resin composition according to the preferred embodiment of the present invention, it is appropriate that the bismaleimide resin is used in a content of 1 to 10 wt %, but the content of the used bismaleimide resin is not specifically limited thereto. In the case in which the content of the used bismaleimide resin is less than 1 wt %, a glass transition temperature of the resin composition may be deteriorated, and in the case in which the content thereof is more than 10 wt %, adhesion of the resin composition is decreased and a curing temperature is increased, such that processability of the printed circuit board may be deteriorated because it is required to perform a stacking process at a high temperature.

Cyanate Ester Resin

The insulating resin composition for a printed circuit board according to the preferred embodiment of the present invention may contain a cyanate ester resin for improving heat-resistant property in the resin composition.

The cyanate ester resin may be a phenol novolac typed cyanate ester resin represented by the following Chemical Formula 5:

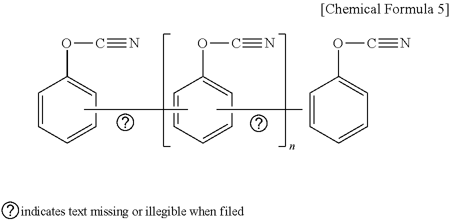

in Chemical Formula 5, n is an integer of 0 to 3.

In the insulating resin composition for a printed circuit board according to the preferred embodiment of the present invention, it is appropriate that the cyanate ester resin is used in a content of 5 to 30 wt %, but the content of the used cyanate ester resin is not specifically limited thereto. In the case in which the content of the used cyanate ester resin is less than 5 wt %, dielectric constant, coefficient of thermal expansion, and shrinkage properties of the resin composition may be increased, and in the case in which the content thereof is more than 30 wt %, a viscosity of the resin composition is decreased, such that an impregnation processability may be deteriorated.

Coupling Agent

The insulating resin composition for a printed circuit board according to the preferred embodiment of the present invention may contain a coupling agent for improving adhesion between the resin composition and an inorganic filler.

The coupling agent may be a silane-based coupling agent. For example, the coupling agent may be at least one selected from vinyltrimethoxysilane, vinyltriethoxysilane, 2-(3,4 epoxycyclohexyl)ethyltrimethoxysilane, 3-glycidoxypropylmethyldiethoxysilane, 3-glycidoxypropyltriethoxysilane, p-styryltrimethoxysilane), 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, (N-2-(aminoethyl)-3-aminopropyltrimethoxysilane, 3-aminopropyltrimethoxysilane, 3-aminopropyltriethoxysilane, 3-triethoxysilyl-N-(1,3dimethyl-butylidene)propylamine, N-(vinylbenzyl)-2-aminoethyl-3-aminopropyltrimethoxysilane hydrochloride, N-(vinylbenzyl)-2-aminoethyl-3-aminopropyltrimethoxysilane hydrochloride, hydrolysate), 3-ureidopropyltriethoxysilane, 3-mercaptopropylmethyldimethoxysilane, 3-mercaptopropyltrimethoxysilane, bis(triethoxysilylpropyl)tetrasulfide, 3-isocyanatepropyltriethoxysilane, 3-glycidoxypropyltrimethoxysilane, N-phenyl-3-aminopropyltrimethoxysilane, among them, 3-glycidoxypropyltrimethoxysilane, N-phenyl-3-aminopropyltrimethoxysilane, or a mixture thereof may be the most appropriate.

In the insulating resin composition according to the preferred embodiment of the present invention, it is appropriate that the coupling agent is used in a content of 0.1 to 5 wt %, but the content of the used coupling agent is not specifically limited thereto. In the case in which the content of the used coupling agent is less than 0.1 wt %, a coupling effect is not sufficiently obtained, such that adhesion between the inorganic filler and the resin composition may be deteriorated, and in the case in which the content thereof is more than 5 wt %, glass transition temperature and coefficient of thermal expansion of the resin composition may be deteriorated.

Eucryptite Inorganic Filler

The insulating resin composition for a printed circuit board according to the preferred embodiment of the present invention may contain an eucryptite inorganic filler having a negative coefficient of thermal expansion in order to decrease coefficient of thermal expansion of the resin composition.

The eucryptite inorganic filler may be represented by the following Chemical Formula 6:

xLi₂0-yAl₂O₃-zSiO₂ [Chemical Formula 6]

In Chemical Formula, each x, y and z represents a mixing molar ratio, x and y are each independently 0.9 to 1.1, and z is 1.2 to 2.1.

The eucryptite inorganic filler is a crystallized glass consisting of Li₂O, Al₂O₃, and SiO₂ components, and in x, y and z representing the mixing molar ratio of each component, x and y are each respectively 0.9 to 1.1, and z is 1.2 to 2.1. Since the eucryptite inorganic filler has a negative coefficient of thermal to an improved coefficient of thermal expansion and has an amorphous shape to have a large specific surface area, such that in the case in which the eucryptite inorganic filler is applied to the resin composition having a small molecular weight, a problem that impregnation process is difficult due to low density may be resolved.

In the insulating resin composition according to the preferred embodiment of the present invention, it is appropriate that the eucryptite inorganic filler is used in a content of 50 to 80 wt %, but the content of the used eucryptite inorganic filler is not specifically limited thereto. In the case in which the content of the used eucryptite inorganic filler is less than 50 wt %, coefficient of thermal expansion may not be decreased, an impregnation processability may be deteriorated due to a decrease in a viscosity of a varnish, and in the case in which the content thereof is more than 80 wt %, flowability of the varnish may be deteriorated due to a lack of content of the resin composition, such that the eucryptite inorganic filler having a content of more than 80 wt % may not be applied to a substrate.

The insulating resin composition for a printed circuit board according to the preferred embodiment of the present invention may further contain a curing agent, a curing accelerator, and an initiator.

The curing agent may be at least one selected from an amine-based curing agent, an acid anhydride-based curing agent, a polyamine curing agent, a polysulfide curing agent, a phenol novolac typed curing agent, a bisphenol A typed curing agent, and a dicyandiamide curing agent, but the present invention is not specifically limited thereto.

Examples of the curing accelerator may include a metal-based curing agent, an imidazole-based curing agent, an amine-based curing agent, and the like, and one kind or two or more kinds of curing accelerator may be used.

Examples of the metal-based curing accelerator may include an organic metal complex or an organic metal salt of a metal such as cobalt, copper, zinc, iron, nickel, manganese, tin, or the like. Specific examples of the organic metal complex may include organic cobalt complex such as cobalt (II) acetylacetonate, cobalt (III) acetylacetonate, or the like, organic copper complex such as copper (II) acetylacetonate, organic zinc complex such as zinc (II) acetylacetonate, organic iron complex such as iron (III) acetylacetonate, organic nickel complex such as Ni (II) acetylacetonate, organic manganese complex such as manganese (II) acetylacetonate, and the like. Examples of the organic metal salts may include zinc octyl acid, tin octyl acid, zinc naphthenic acid, cobalt naphthenic acid, tin stearic acid, zinc stearic acid, and the like. As the metal-based curing accelerator, cobalt (II) acetylacetonate, cobalt (acetylacetonate, zinc (II) acetylacetonate, zinc naphthenic acid, iron (acetylacetonate are preferred, and in particular, cobalt (II) acetylacetonate and zinc naphthenic acid are more preferred. One kind or a combination of two or more kinds of the metal-based curing accelerator may be used.

Examples of the imidazole-based curing accelerator may include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazoliumtrimellitate, 1-cyanoethyl-2-phenylimidazoliumtrimellitate, 2,4-diamino-6-[2′-methylimidazolyl-(1′)]ethyl-s-triazine, 2,4-diamino-6-[2′-undecylimidazolyl-(1′)]ethyl-s-triazine, 2,4-diamino-6-[2′-ethyl-4′-methylimidazolyl-(1′)]-ethyl-s-triazine, 2,4-diamino-6-[2′-methylimidazolyl-(1′)]ethyl-s-triazineisocyanuric acid adduct, 2-phenyl-imidazoleisocyanuric acid adduct, 2-phenyl-4,5-dihydroxymethylimidazole, 2-phenyl-4-methyl-5-hydroxymethylimidazole, 2,3-dihydroxy-1H-pyroro[1,2-a]benzimidazole, 1-dodecyl-2-methyl-3-benzyl-imidazoliumchloride, 2-methylimidazoline, and 2-phenyl-imidazoline, and an adduct of the imidazole compounds and the epoxy resin. One kind or a combination of two or more kinds of the imidazole-based curing accelerator may be used.

Examples of the amine-based curing accelerator may include trialkylamine such as triethylamine and tributylamine, and an amine compound such as 4-dimethylaminopyridine, benzyldimethylamine, 2,4,6-tris(dimethylamino-methyl)phenol, 1,8-diazabicyclo(5,4,0)-undecene. One kind or a combination of two or more kinds of the amine-based curing accelerator may be used.

The initiator may be at least one selected from azobisisobutyronitrile (AIBN), dicumyl peroxide (DCP) and di-tertiarybutyl peroxide (DTBP), but the present invention is not specifically limited thereto.

The insulating resin composition according to the preferred embodiment of the present invention may be manufactured as a dry film in a semi solid state by using any general methods known in the art. For example, the film is manufactured by using a roll coater, a curtain coater, a comma coater, or the like, and dried, and then applied on a substrate to be used as the insulating layer (or the insulating film) or the prepreg at the time of manufacturing a multilayer printed circuit board by a build-up scheme. The insulating film or the prepreg may have the improved coefficient of thermal expansion and glass transition temperature properties.

As described above, an inorganic fiber or an organic fiber is impregnated into a varnish containing the insulating resin composition for a printed circuit board according to the preferred embodiment of the present invention and a drying process is performed, such that the prepreg may be prepared.

The inorganic fiber or the organic fiber may be at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber, but the present invention is not specifically limited thereto.

In addition, the insulating films or the prepregs prepared by using the insulating resin composition for a printed circuit board according to the preferred embodiment of the present invention are stacked on a copper clad laminate (CCL) used as an inner layer at the time of manufacturing the printed circuit board, thereby being used in manufacturing the printed circuit board. For example, after the insulating films or the prepregs manufactured by using the insulating resin composition for a printed circuit board are stacked on the inner layer of the circuit board having processed patterns formed thereon and cured, a desmear process is performed thereon and an electroplating process is performed to form circuit layers, thereby manufacturing the printed circuit board.

Hereinafter, the present invention will be described in more detail with reference to the following examples and comparative examples; however, it is not limited thereto.

### Preparation of Varnish

### Example 1

3 kg of an eucryptite inorganic filler powder was dispersed into 750 g of a N,N′-dimetylacetamide (DMAc) solvent to prepare a slurry having a solid content of 80%, and as additives, 30 g of a dispersion and 60 g of 3-glycidoxypropyltrimethoxysilaneas a silane coupling agent were added thereto.

100 g of an oligomer of phenyl methane maleimide as a bismaleimide resin was added to the slurry, followed by stirring with a stirrer for about 1 hour. Then, after it was confirmed that the bismaleimide resin was completely dissolved, 500 g of bis(2,7-bis(2,3-epoxypropoxy))dinaphthalene methane which is a naphthalene-based epoxy resin having four functional groups was added thereto, followed by stirring with a stirrer for about 2 hours. Next, after it was confirmed that the epoxy resin was completely dissolved, 400 g of a phenol novolac typed cyanate ester resin was added thereto, followed by stirring with a stirrer for about 1 hour. After it was confirmed that the cyanate ester resin was completely dissolved, 2-ethyl-4-methylimidazole (2E4MZ) as a curing catalyst, ditertiarybutylperoxide (DTBP) as a radical reaction initiator of the bismaleimide resin, manganese (II) acetylacetonate (Mn2AA) as a metal catalyst were put thereinto, followed by stirring for about 1 hour to be completely dissolved, thereby preparing a varnish. The varnish had a viscosity of 500 cps measured by using a Brook field viscometer having a condition of 100 rpm.

### Example 2

After the varnish having an adequate content and prepared according to Example 1 above was poured onto a smooth shiny surface of a copper clad, a film having a thickness of about 150 μm was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to manufacture a measuring sample.

### Example 3

A varnish in Example 3 was prepared by the same conditions and method as Example 1 above except for adding 60 g of N-phenyl-3-aminopropyltrimethoxysilane rather than 3-glycidoxypropyltrimethoxysilane as a silane coupling agent. The varnish had a viscosity of 500 cps measured by using a Brook field viscometer having a condition of 100 rpm.

### Example 4

After the varnish having an adequate content and prepared according to Example 3 above was poured onto a smooth shiny surface of a copper clad, a film having a thickness of about 150 μm was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to manufacture a measuring sample.

### Comparative Example 1

3 kg of a spherical silica powder was dispersed into 750 g of an N,N′-dimetylacetamide (DMAc) solvent to prepare a sluny having a solid content of 80%, and a dispersion as an additive was added thereto.

100 g of an oligomer of phenyl methane maleimide as a bismaleimide resin was added to the slurry, followed by stiffing with a stirrer for about 1 hour. Next, after it was confirmed that the bismaleimide resin was completely dissolved, Araldite MY-721 (Huntsman Corporation) 500 g as an epoxy resin was added thereto, followed by stirring with a stirrer for about 2 hours. Next, after it was confirmed that the epoxy resin was completely dissolved, 400 g of a phenol novolac typed cyanate ester resin was added thereto, followed by stirring with a stirrer for about 1 hour. After it was confirmed that the cyanate ester resin was completely dissolved, 2-ethyl-4-methylimidazole (2E4MZ) as a curing catalyst, ditertiarybutylperoxide (DTBP) as a radical reaction initiator of the bismaleimide resin, manganese (II) acetylacetonate (Mn2AA) as a metal catalyst were put thereinto, followed by stirring for about 1 hour to be completely dissolved, thereby preparing a varnish. The varnish had a viscosity of 400 cps measured by using a Brook field viscometer having a condition of 100 rpm.

### Comparative Example 2

After the varnish having an adequate content and prepared according to the Comparative Example 1 above was poured onto a smooth shiny surface of a copper clad, a film having a thickness of about 150 μm was obtained by a film caster for a lab. The film was primarily dried in an oven at about 80° C. for 30 minutes to remove a volatile solvent. Then, the film was secondarily dried at about 120° C. for 60 minutes to obtain a film at a B-stage. The film was completely cured by maintaining a temperature of about 220° C., and pressure of 30 kgf/cm² for about 90 minutes. After the curing was completed, the film was cut into a size of 4.3 mm/30 mm to manufacture a measuring sample.

Coefficients of thermal expansion of samples manufactured according to Examples 2 and 4, and Comparative Example 2 were measured in a tensile mode by using a thermo mechanical analyzer (TMA) of TA Instruments and were calculated based on data obtained by primarily scanning the sample for each 10° C. per minute up to 300° C., followed by cooling, and then secondarily scanning the sample for each 10° C. per minute up to 310° C.

In addition, glass transition temperatures thereof were measured in a tension mode by using a dynamic mechanical analyzer (DMA) of TA Instruments, and were calculated based on data obtained by scanning the sample for each 3° C. per minute up to 350° C. and calculating an initial storage modulus and the maximum value of tan δ (a ratio of a loss modulus to a storage modulus).

TABLE 1

| | Coefficient of | Glass Transition |
|---|---|---|
| | Thermal Expansion | Temperature |
| Classification | (ppm/° C.) | (° C.) |
| Example 2 | 5.0 | 303 |
| Example 4 | 5.7 | 295 |
| Comparative | 10.2 | 200 |
| Example 2 | | |

It may be appreciated from Table 1 above that the coefficients of thermal expansion of Examples 2 and 4 were smaller than that of Comparative Example 2, and the glass transition temperatures thereof were remarkably excellent than that of Comparative Example 2.

It may be appreciated that the measuring samples having the insulating resin composition of the present invention applied thereto and manufactured according to Examples 2 and 4 include the eucryptite inorganic filler having a negative coefficient of thermal expansion, such that the glass transition temperature and the coefficient of thermal expansion may be improved. In addition, the eucryptite inorganic filler may be surface-treated with the silane-based coupling agent on the surface thereof, such that the adhesion between the resin compositions may be improved.

Further, since the eucryptite inorganic filler has an amorphous shape, it has a large specific surface area, such that in the case of in which the eucryptite inorganic filler is applied to the resin composition having a small molecular weight, a problem that impregnation is difficult due to low density may be resolved.

The insulating film, the prepreg, the copper clad laminate, or the printed circuit board manufactured by using the insulating resin composition for a printed circuit board according to the preferred embodiment of the present invention may have the improved glass transition temperature and the improved coefficient of thermal expansion, such that the warpage of the product may be minimized.

### Preparation of Prepreg

### Example 5

After the varnish solution having an adequate content and prepared according to Example 1 above was poured into an impregnation bath of an impregnation device, a glass fiber (1078, manufactured by BAO EK, Inc.) was impregnated into the varnish in the impregnation device, and put into an oven to perform a drying process at about 120° C. for 15 minutes. When the drying process was completed, the temperature was raised up to 220° C., and the reactant was completely cured by maintaining a temperature of about 220° C. and a pressure of 30 kgf/cm² for about 90 minutes to prepare a prepreg.

### Manufacturing of Printed Circuit Board

### Example 6

After copper clads having a thickness of 20 μm were stacked on both surfaces of the prepreg prepared according to Example 5 above so that a mat surface is folded, a temperature was raised up to 220° C. in a laminator, and the reactant was completely cured at a temperature of 220° C. and a pressure of 30 kgf/cm² for about 90 minutes to manufacture a copper clad laminate (CCL). After the copper clad layers of the manufactured copper clad laminate was provided with circuit patterns and a drying process was performed under conditions having a temperature of about 120° C. for about 30 minutes, additional build-up layers were stacked on the circuit pattern, a Morton CVA 725 vacuum laminator was used to be subject to a vacuum lamination under conditions having a temperature of about 90° C. and 2 MPa for about 20 seconds to thereby manufacture a printed circuit board.

The insulating resin composition for a printed circuit board and products manufactured by using the same according to the preferred embodiments of the present invention may contain the eucryptite inorganic filler having a negative coefficient of thermal expansion, such that the glass transition temperature and the coefficient of thermal expansion may be improved.

In addition, the eucryptite inorganic filler may be surface-treated with the silane-based coupling agent on the surface thereof, such that the adhesion between the resin compositions may be improved.

Further, since the eucryptite inorganic filler has an amorphous shape, it has a large specific surface area. Therefore, in the case in which the eucryptite inorganic filler is applied to a resin composition having a small molecular weight, a problem that impregnation is difficult due to low density may be resolved.

The insulating film, the prepreg, the copper clad laminate, or the printed circuit board manufactured by using the insulating resin composition for a printed circuit board according to the preferred embodiment of the present invention may have the improved glass transition temperature and the improved coefficient of thermal expansion, such that warpage of the product may be minimized.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An insulating resin composition for a printed circuit board comprising:
a naphthalene-based epoxy resin;
a bismaleimide resin;
a cyanate ester resin;
a coupling agent; and
an eucryptite inorganic filler.

2. The insulating resin composition for a printed circuit board as set forth in claim 1, wherein the naphthalene-based epoxy resin is contained in a content of 5 to 30 wt %, the bismaleimide resin is contained in a content of 1 to 10 wt %, the cyanate ester resin is contained in a content of 5 to 30 wt %, the coupling agent is contained in a content of 0.1 to 5 wt %; and the eucryptite inorganic filler is contained in a content of 50 to 80 wt %.

3. The insulating resin composition for a printed circuit board as set forth in claim 1, wherein the naphthalene-based epoxy resin is a methane typed naphthalene-based epoxy resin represented by the following Chemical Formula 1, an ester typed naphthalene-based epoxy resin represented by the following Chemical Formula 2 or 3, or a mixture thereof:

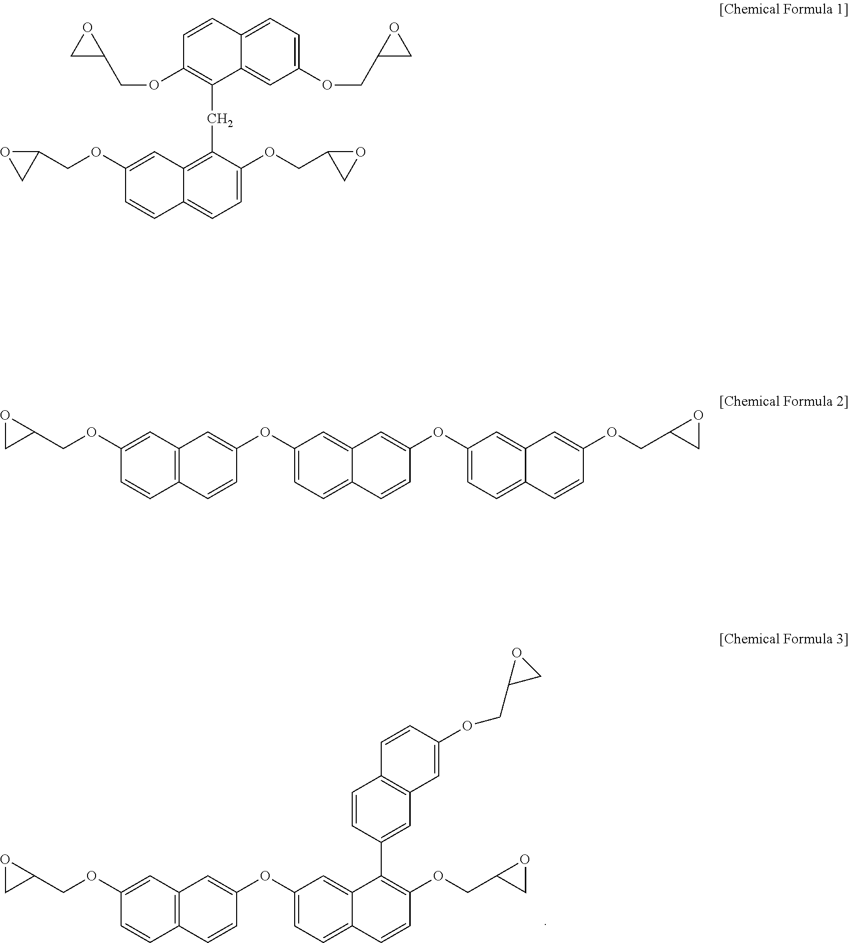 [SMILES: c1cc2ccc(OCC3CO3)c(Cc3c(OCC4CO4)ccc4ccc(OCC5CO5)cc34)c2cc1OCC1CO1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

4. The insulating resin composition for a printed circuit board as set forth in claim 1, wherein the bismaleimide resin is an oligomer of phenyl methane maleimide represented by the following Chemical Formula 4: 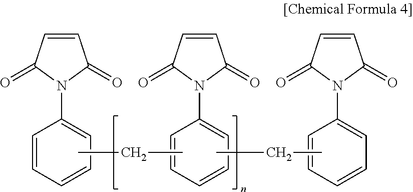
in Chemical Formula 4, n is an integer of 0 to 2.

5. The insulating resin composition for a printed circuit board as set forth in claim 1, wherein the cyanate ester resin is a phenol novolac typed cyanate ester resin represented by the following Chemical Formula 5: 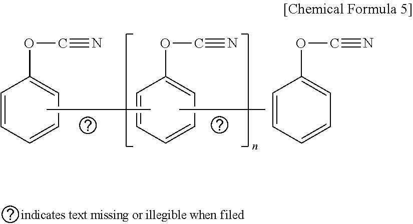
in Chemical Formula 5, n is an integer of 0 to 3.

6. The insulating resin composition for a printed circuit board as set forth in claim 1, wherein the coupling agent is a silane-based coupling agent.

7. The insulating resin composition for a printed circuit board as set forth in claim 1, wherein the eucryptite inorganic filler is represented by the following Chemical Formula 6:
xLi₂0-yAl₂O₃-zSiO₂ [Chemical Formula 6]
in Chemical Formula 6, each x, y and z represents a mixing molar ratio, x and y are each independently 0.9 to 1.1, and z is 1.2 to 2.1.

8. The insulating resin composition for a printed circuit board as set forth in claim 1, further comprising a curing agent, a curing accelerator, and an initiator.

9. The insulating resin composition for a printed circuit board as set forth in claim 8, wherein the curing agent is at least one selected from an amine-based curing agent, an acid anhydride-based curing agent, a polyamine curing agent, a polysulfide curing agent, a phenol novolac typed curing agent, a bisphenol A typed curing agent, and a dicyandiamide curing agent.

10. The insulating resin composition for a printed circuit board as set forth in claim 8, wherein the curing accelerator is at least one selected from a metal-based curing accelerator, an imidazole-based curing accelerator, and an amine-based curing accelerator.

11. The insulating resin composition for a printed circuit board as set forth in claim 8, wherein the initiator is at least one selected from azobisisobutyronitrile (AIBN), dicumyl peroxide (PCP) and di-tertiarybutyl peroxide (DTBP).

12. A prepreg prepared by impregnating an inorganic fiber or an organic fiber into a varnish containing the insulating resin composition for a printed circuit board as set forth in claim 1.

13. The prepreg as set forth in claim 12, wherein the inorganic fiber or the organic fiber is at least one selected from a glass fiber, a carbon fiber, a polyparaphenylene benzobisoxazol fiber, a thermotropic liquid crystal polymer fiber, a lithotropic liquid crystal polymer fiber, an aramid fiber, a polypyridobisimidazole fiber, a polybenzothiazole fiber, and a polyarylate fiber.

14. A printed circuit board manufactured by stacking at least one circuit layer and insulating layer on one surface or the other surface of the prepreg as set forth in claim 12.
